(19) United States
(12) Patent Application Publication
(10) Pub. No.: US 2023/0185000 A1
(43) Pub. Date: Jun. 15, 2023

(54) HIGH PRECISION NANOSCALE THIN FILM FABRICATION PROCESSES

(71) Applicant: SDS Nano, Inc., Austin, TX (US)

(72) Inventors: Shrawan Singhal, Austin, TX (US); Sidlgata V. Sreenivasan, Austin, TX (US)

(21) Appl. No.: 17/925,490

(22) PCT Filed: May 18, 2021
(86) PCT No.: PCT/US2021/032989

§ 371 Date: Nov. 15, 2022

Related U.S. Application Data
(60) Provisional application No. 63/026,215, filed on May 18, 2020.
(60) Provisional application No. 63/031,681, filed on May 29, 2020.

(51) Int. Cl. G02B 3/00; B29D 11/00; G02B 1/00; G02B 1/12

(52) U.S. Cl. CPC G02B 3/0068; B29D 11/00326; B29D 11/00346; B29D 11/00442; G02B 1/002; G02B 1/12; G02B 2207/101

(57) ABSTRACT

A method for fabricating one or more elements in a multi-lens column. Drops of ultraviolet (UV)-curable liquid are dispensed by an inkjet on a substrate, which may be supported by a chuck. A non-uniform liquid film is then formed, such as by spreading and merging of the inkjetted drops. The film is then locally heated, such as by using a digital micromirror device array. The film is then cured by exposing it to UV light, where the cured film together with the substrate form an element of the multi-lens column. The substrate is then brought to a metrology station where optical metrology is performed on the cured film and the substrate for quality control.

### TECHNICAL FIELD

The present invention relates generally to nanoscale thin film deposition, and more particularly to fabricating optical elements in multi-lens columns using the nanoscale precision programmable profiling (nP3) process.

### BACKGROUND

Current state-of-the-art semiconductor patterning includes feature sizes that are well below 100 nm, and in some cases approaching as low as 10 nm. For such high-resolution features, visible wavelengths are no longer sufficient as resolution is directly proportional to the wavelength. Thus, electromagnetic radiation deep in the UV spectrum is needed. Some common wavelengths that are used include 248 nm (Hg vapor), 193 nm (excimer laser) and 157 nm (vacuum UV). At the same time, resolution is increased with increasing numerical aperture of the system, typically greater than 0.9. This can theoretically be achieved by using large diameter lenses. However, these lenses have been traditionally difficult and expensive to fabricate, align and mount in a system. In order to reconcile these constraints, such optical systems are usually designed with a large number of lens elements, typically exceeding 10. By using multiple elements, a high numerical aperture can be achieved by using smaller elements that individually have a lower numerical aperture, but can function together to obtain the desired values for numerical aperture.

However, the use of multiple elements in the optical system introduces other difficulties. One of those difficulties is the presence of “gaps” between individual elements. Ideally, one would like to use optical cements in those gaps, that allow minimal refractive index mismatch across the optical element-gap interface. But the use of excimer lasers and other UV radiation can degrade the quality of those cements rapidly thereby precluding the use of such cements. Hence, instead of cements, the gaps can be let as is, i.e., the gaps can be air gaps. This causes a high refractive index mismatch between the optical element and the air gap, making it important for the optical system to be designed in such a way that the angles of incidence and refraction do not exceed the critical angle for total internal reflection. Moreover, the overall optical system also needs to be designed in such a way that the total optical aberrations in the system do not exceed values that can distort images.

### SUMMARY

In one embodiment of the present invention, a method for fabricating one or more elements in a multi-lens column comprises dispensing drops of ultraviolet (UV)-curable liquid by an inkjet on a substrate. The method further comprises forming a non-uniform liquid film by spreading and merging of the inkjetted drops. The method additionally comprises locally heating the film. Furthermore, the method comprises curing the film by exposing the film to UV light, where the cured film together with the substrate form an element of the multi-lens column. Additionally, the method comprises performing optical metrology on the cured film and the substrate.

In another embodiment of the present invention, a method for fabricating one or more elements in a multi-lens column comprises depositing a cured film on a surface of an imprecise lens to correct external aberrations or inherent aberrations using a nanoscale precise programmable profiling process. The nanoscale precision programming profiling process comprises dispensing drops of ultraviolet (UV)-curable liquid by an inkjet on a substrate. The nanoscale precision programming profiling process further comprises forming a non-uniform liquid film by spreading and merging of the inkjetted drops. The nanoscale precision programming profiling process additionally comprises locally heating the film using a digital micromirror device array. Furthermore, the nanoscale precision programming profiling process comprises curing the film by exposing it to UV light. The method further comprises transferring a profile of the cured film into the substrate by dry etch, where the substrate with the transferred profile of the cured film forms an element of the multi-lens column.

In a further embodiment of the present invention, a multi-lens column one or more optical elements fabricated using a nanoscale precision programmable profiling process and a dry etch process. The nanoscale precision programming profiling process comprises dispensing drops of ultraviolet (UV)-curable liquid by an inkjet on a substrate. The nanoscale precision programming profiling process further comprises forming a non-uniform liquid film by spreading and merging of the inkjetted drops. The nanoscale precision programming profiling process additionally comprises locally heating the film. Furthermore, the nanoscale precision programming profiling process comprises curing the film by exposing it to UV light. Additionally, the nanoscale precision programming profiling process comprises transferring a profile of the cured film into the substrate by the dry etch process, where the substrate with the transferred profile of the cured film forms an optical element of the multi-lens column.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 is a flowchart of a method for the Nanoscale Precision Programmable Profiling (nP3) process on nominally non-flat substrates in accordance with an embodiment of the present invention;

FIG. 2 is a flowchart of a method for fabricating elements, such as for multi-lens columns, on non-flat substrates using the Nanoscale Precision Programmable Profiling (nP3) process without the use of a superstrate in accordance with an embodiment of the present invention;

FIGS. 3A-3E depict cross-sectional views for fabricating elements, such as for multi-lens columns, using the nP3 process on non-flat substrates without the use of a superstrate using the steps described in FIG. 2 in accordance with an embodiment of the present invention;

FIG. 4 is a flowchart of a method for fabricating elements, such as for multi-lens columns, on flat substrates using the Nanoscale Precision Programmable Profiling (nP3) process without the use of a superstrate in accordance with an embodiment of the present invention;

FIGS. 5A-5E depict cross-sectional views for fabricating elements, such as for multi-lens columns, on flat substrates using the nP3 process without the use of a superstrate using the steps described in FIG. 4 in accordance with an embodiment of the present invention;

FIG. 6 is a flowchart of a method for fabricating elements, such as for multi-lens columns, on flat substrates using the Nanoscale Precision Programmable Profiling (nP3) process with the use of a superstrate in accordance with an embodiment of the present invention;

FIGS. 7A-7E depict cross-sectional views for fabricating elements, such as for multi-lens columns, on flat substrates using the nP3 process with the use of a superstrate using the steps described in FIG. 6 in accordance with an embodiment of the present invention.

FIG. 8 is a flowchart of a method for fabricating elements for multi-lens columns using the nP3 process on an imprecise lens in accordance with an embodiment of the present invention;

FIGS. 9A-9C depict cross-sectional views for fabricating elements, such as for multi-lens columns, using the nP3 process, on an imprecise lens using the steps described in FIG. 8 in accordance with an embodiment of the present invention;

FIG. 10 is a flowchart of an alternative method for fabricating elements for multi-lens columns using the nP3 process on an imprecise lens in accordance with an embodiment of the present invention;

FIGS. 11A-11C depict cross-sectional views for fabricating elements, such as for multi-lens columns, using the nP3 process, on an imprecise lens using the steps described in FIG. 10 in accordance with an embodiment of the present invention;

FIG. 12 illustrates an example of a multi-lens optical system in accordance with an embodiment of the present invention;

FIG. 13 illustrates an element fabricated using nP3 that is part of the original system in accordance with an embodiment of the present invention; and

FIG. 14 illustrates corrector plates that are fabricated using the nP3 process and added to the original system to improve optical performance and relieve design, fabrication and assembly tolerances for other elements in the system in accordance with an embodiment.

### DETAILED DESCRIPTION

As stated in the Background section, current state-of-the-art semiconductor patterning includes feature sizes that are well below 100 nm, and in some cases approaching as low as 10 nm. For such high-resolution features, visible wavelengths are no longer sufficient as resolution is directly proportional to the wavelength. Thus, electromagnetic radiation deep in the UV spectrum is needed. Some common wavelengths that are used include 248 nm (Hg vapor), 193 nm (excimer laser) and 157 nm (vacuum UV). At the same time, resolution is increased with increasing numerical aperture of the system, typically greater than 0.9. This can theoretically be achieved by using large diameter lenses. However, these lenses have been traditionally difficult and expensive to fabricate, align and mount in a system. In order to reconcile these constraints, such optical systems are usually designed with a large number of lens elements, typically exceeding 10. By using multiple elements, a high numerical aperture can be achieved by using smaller elements that individually have a lower numerical aperture, but can function together to obtain the desired values for numerical aperture.

However, the use of multiple elements in the optical system introduces other difficulties. One of those difficulties is the presence of “gaps” between individual elements. Ideally, one would like to use optical cements in those gaps, that allow minimal refractive index mismatch across the optical element-gap interface. But the use of excimer lasers and other UV radiation can degrade the quality of those cements rapidly thereby precluding the use of such cements. Hence, instead of cements, the gaps can be let as is, i.e., the gaps can be air gaps. This causes a high refractive index mismatch between the optical element and the air gap, making it important for the optical system to be designed in such a way that the angles of incidence and refraction do not exceed the critical angle for total internal reflection. Moreover, the overall optical system also needs to be designed in such a way that the total optical aberrations in the system do not exceed values that can distort images.

The principles of the present invention are used to develop optical systems with total optical aberrations in the system that do not exceed values that can distort images beyond desired tolerances for semiconductor wafer inspection.

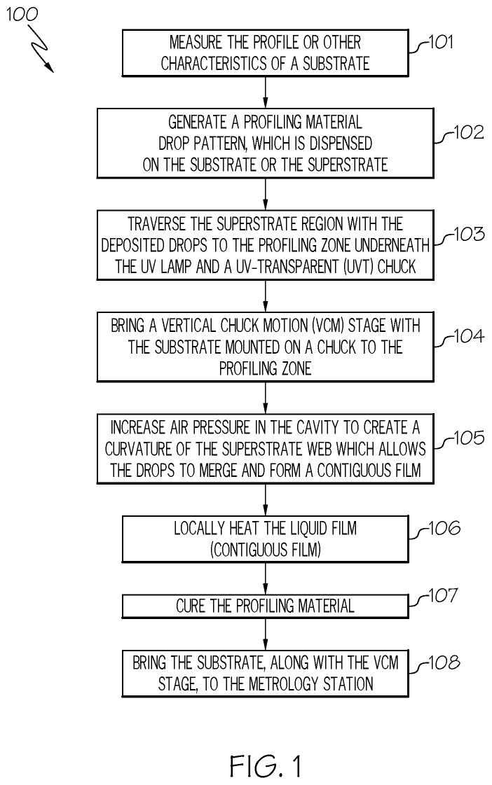

Referring now to the Figures in detail, FIG. 1 is a flowchart of a method 100 for the Nanoscale Precision Programmable Profiling (nP3) process on nominally non-flat substrates. While the following description is related to substrates with a nominal curvature, other substrate profiles, such as flat, aspheric, freeform, etc. can also be processed using the same process.

Referring to FIG. 1, in step 101, the profile or other characteristics of a substrate are measured.

In step 102, a profiling material drop pattern is generated and dispensed on the substrate or the superstrate. In one embodiment, the superstrate is nominally a non-patterned roll of flexible material, such as polycarbonate, PET, PEN, etc., but can also be a textured or patterned roll, where the lateral spatial length scale of the texture or pattern is at least an order of magnitude lower than the lateral spatial length scale of the desired profile.

In one embodiment, the superstrate web speed is synchronized with the dispensing timing cycle to maintain drop placement accuracy. In one embodiment, the drop locations also correspond to the desired locations on the substrate such that upon conformal contact with the substrate, the drops are located at where they need to be on the substrate.

In step 103, the superstrate region with the deposited drops is traversed to the profiling zone underneath the ultraviolet (UV) lamp and a UV-transparent (UVT) chuck. Tension in the superstrate is adjusted to the desired level as necessitated by the final surface profile. In one embodiment, the UVT chuck is used to then hold the superstrate in place.

In step 104, a vertical chuck motion (VCM) stage with the substrate mounted on a chuck are brought to the profiling zone with the help of the horizontal XY stages. The VCM stage may be actuated using voice coils, piezoelectric actuators, pneumatic actuators, etc. In one embodiment, the chuck can be a three pin mount to support varying curvatures. In one embodiment, the vertical tip tilt motion of the VCM stage allows proper alignment of substrate with superstrate and gap control.

In step 105, air pressure is increased in the cavity to create a curvature of the superstrate web which allows the drops to merge and form a contiguous film. This allows mitigation of any entrapped air bubbles. Cameras mounted on the UVT chuck are used to observe bubble entrapment. Using image processing, bubbles are identified and air is automatically pumped on the superstrate at targeted locations to ensure drops there spread and the bubbles are mitigated.

In step 106, the liquid film (contiguous film) is locally heated with the help of a spatially modulated thermal actuator, such as an infrared radiation source projected through a digital micromirror device array or distributed micro-heater or a laser source mounted on a stage that can be rapidly scanned across the substrate. The local heating allows for additional control of the film thickness profile.

In step 107, after a specified amount of time necessary for capillary and thermal forces to create the desired topography, the profiling material is UV cured. The VCM stage is used to separate the substrate from the superstrate through its vertical motion.

In step 108, the substrate, along with the VCM stage, is brought to the metrology station. The VCM stage helps align the normal to the curved face of the substrate at the point of measurement with the optical axis of a measurement system, such as an interferometer, an aberrometer, or a Shack-Hartmann wavefront sensor. A laser beam is transmitted through the substrate onto the measurement system through an automated telescopic system (to account for different powers). The XY stages are used to scan the substrate in the horizontal plane to measure topography at every location on the substrate. Once the measurement is performed, a decision is made on whether further processing is required (in-case of multistep processes or to correct for errors in the previous step). The horizontal stages bring the substrate back to the profiling zone if processing is required. In one embodiment, the communication module in the tool can be used to transfer and exchange data related to substrate metrology, tool sensors and drop pattern.

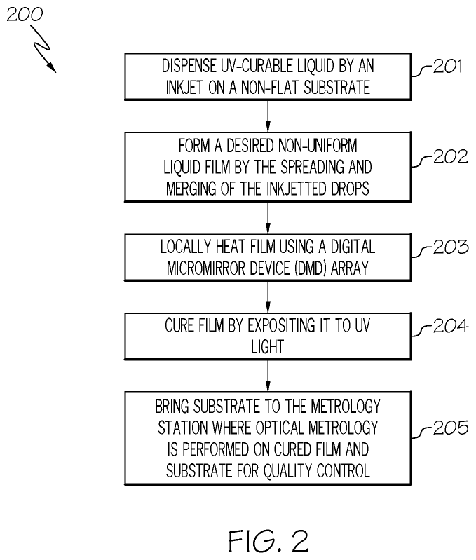

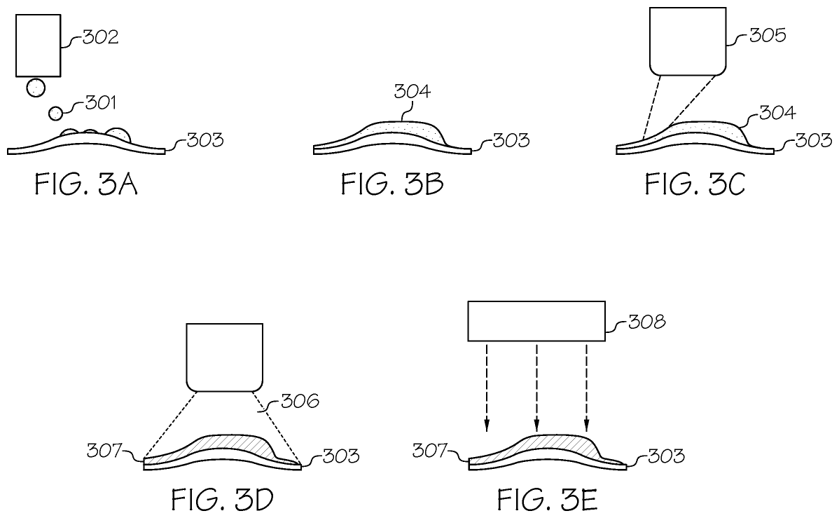

FIG. 2 is a flowchart of a method 200 for fabricating elements, such as for multi-lens columns, on non-flat substrates using the Nanoscale Precision Programmable Profiling (nP3) process without the use of a superstrate in accordance with an embodiment of the present invention. FIGS. 3A-3E depict cross-sectional views for fabricating elements, such as for multi-lens columns, using the nP3 process on non-flat substrates without the use of a superstrate using the steps described in FIG. 2 in accordance with an embodiment of the present invention.

Referring to FIG. 2, in conjunction with FIGS. 3A-3E, in step 201, drops of UV-curable liquid 301 (e.g., mrUVCur26-SF from MicroResist® Technologies) are dispensed by an inkjet 302 on a non-flat substrate 303 as illustrated in FIG. 3A. In one embodiment, the amount of UV-curable liquid 301 that is dispensed by inkjet 302 is based on a desired film thickness profile.

In step 202, a desired non-uniform liquid film 304 is formed by the spreading and merging of the inkjetted drops 301 as shown in FIG. 3B.

In step 203, film 304 is locally heated using a digital micromirror device (DMD) array 305 as shown in FIG. 3C. In one embodiment, DMD array 305 (e.g., digital light processing (DLP) chipsets from Texas Instruments®) corresponds to an optical micro-electrical-mechanical system (MEMS) that contains an array of highly reflective aluminum mircromirrors, which reflect IR light, such as onto film 304. In one embodiment, the infrared (IR) light consists of a wavelength range between 1,000-11,000 nm. In one embodiment, the IR light source is an IR laser. In one embodiment, local hearing of film 304 is performed using one or more of the following: an infrared light source projected using DMD array 305, distributed microheaters, and an infrared laser source mounted on a stage.

In one embodiment, DMD array 305 enables ultra-precise profiling by spatio-temporal control of thermal and flow gradients.

In step 204, after a specified amount of time necessary for capillary and thermal forces to create the desired topography, film 304 is UV cured by expositing it to UV light 306 thereby forming the cured film 307, which together with substrate 303 forms an element of a multi-lens column as shown in FIG. 3D.

In step 205, substrate 303 is then brought to the metrology station where optical metrology 308 is performed on cured film 307 and substrate 303 for quality control as shown in FIG. 3E. In one embodiment, the optical metrology is carried out in-situ simultaneously with steps 202 and 203 to enable real-time feedback and control.

In one embodiment, an optional reaction ion or dry etching step may be performed following the nP3 process.

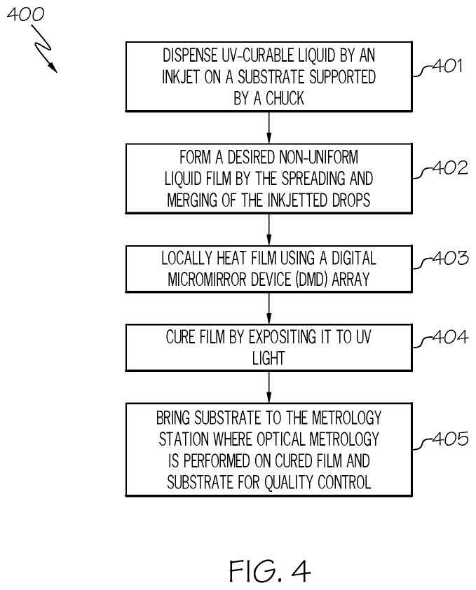

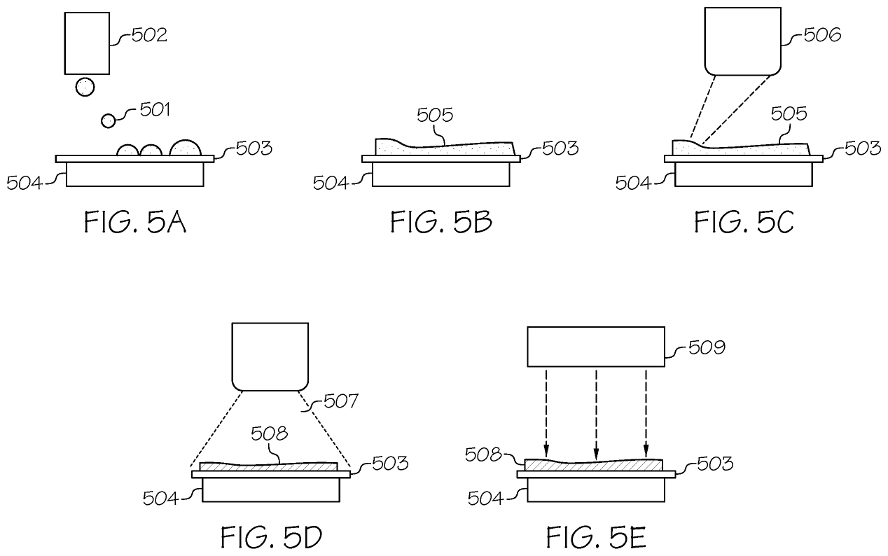

FIG. 4 is a flowchart of a method 400 for fabricating elements, such as for multi-lens columns, on flat substrates using the Nanoscale Precision Programmable Profiling (nP3) process without the use of a superstrate in accordance with an embodiment of the present invention. FIGS. 5A-5E depict cross-sectional views for fabricating elements, such as for multi-lens columns, on flat substrates using the nP3 process without the use of a superstrate using the steps described in FIG. 4 in accordance with an embodiment of the present invention.

Referring to FIG. 4, in conjunction with FIGS. 5A-5E, in step 401, drops of UV-curable liquid 501 are dispensed by an inkjet 502 on a flat substrate 503 supported by a chuck 504 as illustrated in FIG. 5A. In one embodiment, the amount of UV-curable liquid 501 that is dispensed by inkjet 502 is based on a desired film thickness profile.

In step 402, a desired non-uniform liquid film 505 is formed by the spreading and merging of the inkjetted drops 501 as shown in FIG. 5B.

In step 403, film 505 is locally heated using a digital micromirror device (DMD) array 506 as shown in FIG. 5C. In one embodiment, DMD array 506 (e.g., digital light processing (DLP) chipsets from Texas Instruments®) corresponds to an optical micro-electrical-mechanical system (MEMS) that contains an array of highly reflective aluminum micrromirrors, which reflect IR light, such as onto film 505. In one embodiment, the IR light consists of a wavelength range between 1,000-11,000 nm. In one embodiment, the IR light source is an IR laser. In one embodiment, local hearing of film 505 is performed using one or more of the following: an infrared light source projected using DMD array 506, distributed microheaters, and an infrared laser source mounted on a stage.

In one embodiment, DMD array 506 enables ultra-precise profiling by spatio-temporal control of thermal and flow gradients.

In step 404, after a specified amount of time necessary for capillary and thermal forces to create the desired topography, film 505 is UV cured by expositing it to UV light 507 thereby forming the cured film 508, which together with substrate 503 forms an element of a multi-lens column as shown in FIG. 5D.

In step 405, substrate 503 is then brought to the metrology station where optical metrology 509 is performed on cured film 508 and substrate 503 for quality control as shown in FIG. 5E. In one embodiment, the optical metrology is carried out in-situ simultaneously with steps 402 and 403 to enable real-time feedback and control.

In one embodiment, an optional reaction ion or dry etching step may be performed following the nP3 process.

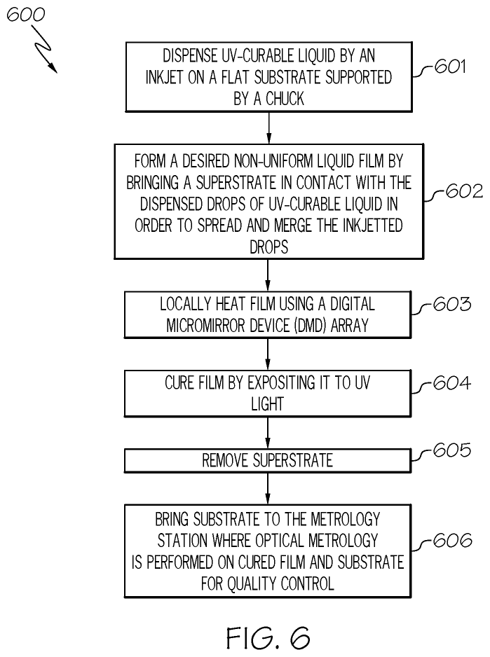

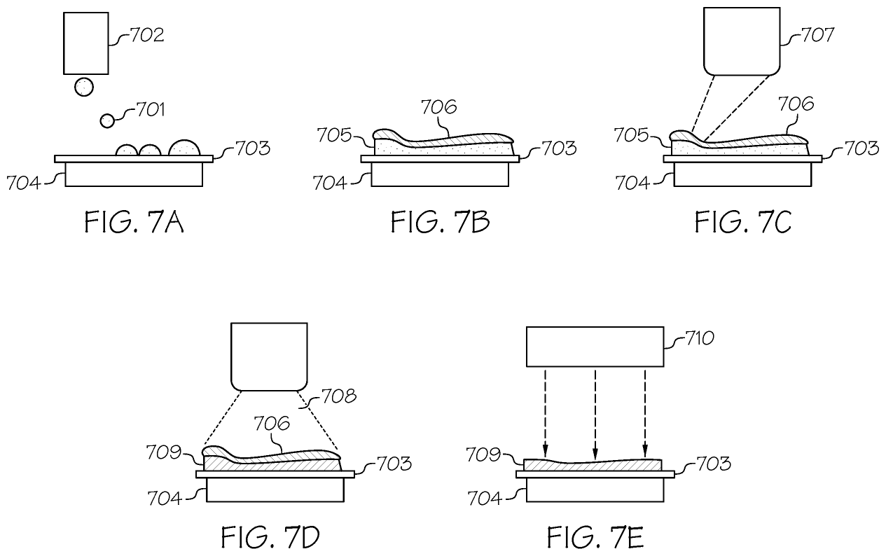

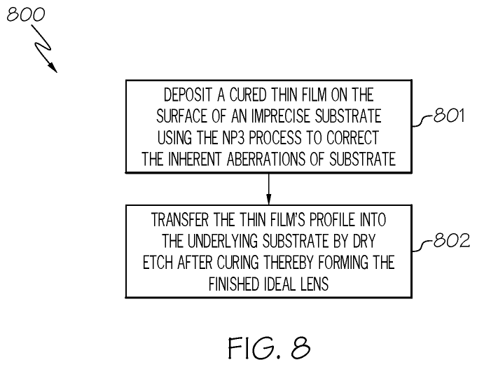

FIG. 6 is a flowchart of a method 600 for fabricating elements, such as for multi-lens columns, on flat substrates using the Nanoscale Precision Programmable Profiling (nP3) process with the use of a superstrate in accordance with an embodiment of the present invention. FIGS. 7A-7E depict cross-sectional views for fabricating elements, such as for multi-lens columns, on flat substrates using the nP3 process with the use of a superstrate using the steps described in FIG. 6 in accordance with an embodiment of the present invention.

Referring to FIG. 6, in conjunction with FIGS. 7A-7E, in step 601, drops of UV-curable liquid 701 are dispensed by an inkjet 702 on a flat substrate 703 supported by a chuck 704 as illustrated in FIG. 7A. In one embodiment, the amount of UV-curable liquid 701 that is dispensed by inkjet 702 is based on a desired film thickness profile.

In step 602, a desired non-uniform liquid film 705 is formed by bringing a superstrate 706 in contact with the dispensed drops of UV-curable liquid 701 in order to spread and merge the inkjetted drops 701 as shown in FIG. 7B. In one embodiment, superstrate 706 is nominally a non-patterned roll of flexible material, such as polycarbonate, PET, PEN, etc., but can also be a textured or patterned roll, where the lateral spatial length scale of the texture or pattern is at least an order of magnitude lower than the lateral spatial length scale of the desired profile.

In step 603, film 705 is locally heated using a digital micromirror device (DMD) array 707 as shown in FIG. 7C. In one embodiment, DMD array 707 (e.g., digital light processing (DLP) chipsets from Texas Instruments®) corresponds to an optical micro-electrical-mechanical system (MEMS) that contains an array of highly reflective aluminum mircromirrors, which reflect IR light, such as onto film 705. In one embodiment, the IR light consists of a wavelength range between 1,000-11,000 nm. In one embodiment, the IR light source is an IR laser. In one embodiment, local hearing of film 705 is performed using one or more of the following: an infrared light source projected using DMD array 707, distributed microheaters, and an infrared laser source mounted on a stage.

In one embodiment, DMD array 707 enables ultra-precise profiling by spatio-temporal control of thermal and flow gradients.

In step 604, after a specified amount of time necessary for capillary and thermal forces to create the desired topography, film 705 is UV cured by expositing it to UV light 708 thereby forming the cured film 709, which together with substrate 703 forms an element of a multi-lens column as shown in FIG. 7D.

In step 605, superstrate 706 is removed, such as via etching, as shown in FIG. 7E.

In step 606, substrate 703 is then brought to the metrology station where optical metrology 710 is performed on cured film 709 and substrate 703 for quality control as shown in FIG. 7E. In one embodiment, the optical metrology is carried out in-situ simultaneously with steps 602 and 603 to enable real-time feedback and control.

In one embodiment, an optional reaction ion or dry etching step may be performed following the nP3 process.

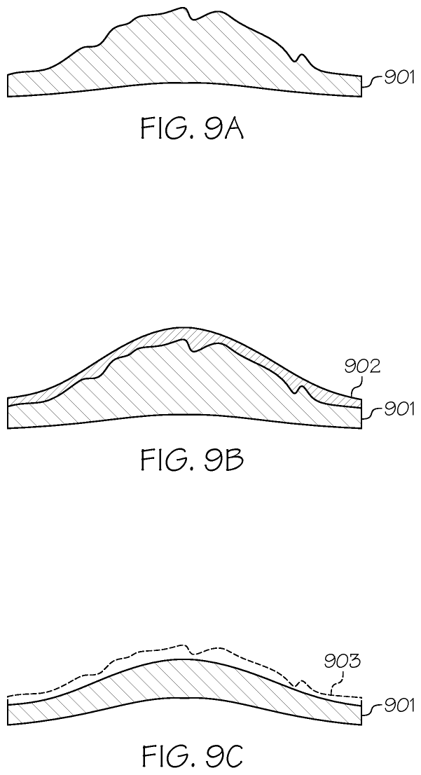

FIG. 8 is a flowchart of a method 800 for fabricating elements for multi-lens columns using the nP3 process on an imprecise lens in accordance with an embodiment of the present invention. FIGS. 9A-9C depict cross-sectional views for fabricating elements, such as for multi-lens columns, using the nP3 process, on an imprecise lens using the steps described in FIG. 8 in accordance with an embodiment of the present invention.

Referring to FIG. 8, in conjunction with FIGS. 9A-9C, in step 801, a thin film 902 is deposited on the surface of an imprecise substrate 901, such as made from different types of glasses (e.g., fused silica, quartz, BK-7, UV-grade fused silica, etc.) or silicon, using the nP3 process to correct the inherent aberrations of substrate 901 as shown in FIGS. 9A-9B. The goal of such a process is to fabricate an ideal substrate.

In step 802, after curing, the thin film's profile 903 is transferred into the underlying substrate 901 by dry etch thereby forming the finished ideal lens as shown in FIG. 9C. In one embodiment, substrate 901 with the transferred profile 903 forms an element of the multi-lens column.

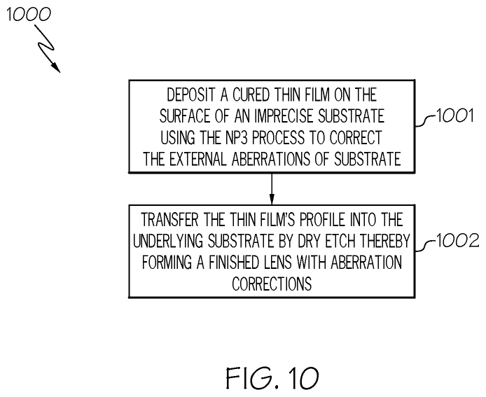

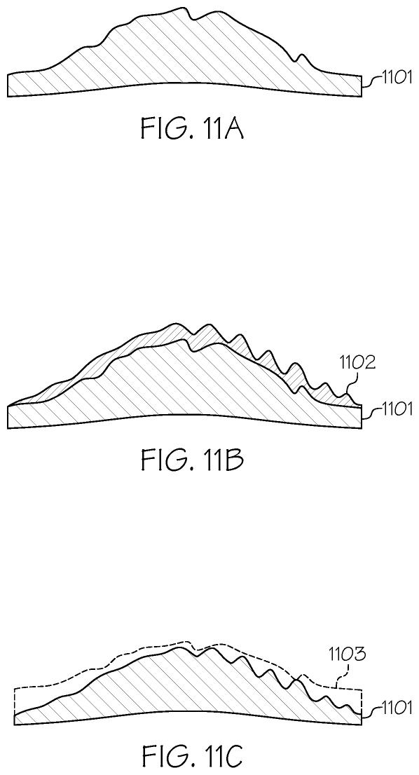

FIG. 10 illustrates a flowchart of an alternative method 1000 for fabricating elements for multi-lens columns using the nP3 process on an imprecise lens in accordance with an embodiment of the present invention. FIGS. 11A-11C depict cross-sectional views for fabricating elements, such as for multi-lens columns, using the nP3 process, on an imprecise lens using the steps described in FIG. 10 in accordance with an embodiment of the present invention.

Referring to FIG. 10, in conjunction with FIGS. 11A-11C, in step 1001, a thin film 1102 is deposited on the surface of an imprecise substrate 1101, such as made from different types of glasses (e.g., fused silica, quartz, BK-7, UV-grade fused silica, etc.) or silicon, using the nP3 process to correct the external aberrations of substrate 1101 as shown in FIGS. 11A-11B. The goal of such a process is to fabricate a lens with aberration corrections.

In step 1002, after curing, the thin film's profile 1103 is transferred into the underlying substrate 1101 by dry etch thereby forming a finished lens with aberration corrections as shown in FIG. 11C. In one embodiment, substrate 1101 with the transferred profile 1103 forms an element of the multi-lens column.

In one embodiment, the nP3 process is used for precision optics. Precision optical elements include mirrors and lenses for a wide variety of applications. Depending on the application, such elements may need to be fabricated from different substrate materials, and can either be flat, freeform or nominally curved. The nP3 process can be used to either correct the existing topography on a substrate to match a desired topography, or can be used to generate an entirely different profile from a starting substrate, in order to lend some desired functional properties to the system, such as minimization of optical aberrations. In some applications, the nP3 process deposits a functional film which is left behind on the substrate. For example, for optical applications, the functional material may be a film with a refractive index which is matched with that of the substrate. For some applications, the nP3 process deposits a sacrificial film which can then be used to transfer the profile of the film into the substrate using an etching step. The relative etch rate ratios between the polymer film and the substrate or underlying film on the substrate can vary from 0.02 to 50. Based on this etch rate ratio, the sacrificial film profile can be altered to get the final desired profile in the substrate. The sacrificial film profile can also be adjusted to compensate for any systematic errors in pre- or post-processing steps, such as the etching step. In some of these applications, the presence of a polymer film can degrade the functionality of the substrate and thus needs to be removed to enable functionality, for example, for high intensity laser beam optics or other high-end precision optical instruments, such as deep UV (DUV) microscope objectives, or those that are used in semiconductor wafer and mask metrology and characterization. In one embodiment, the etching step is conducted in a reactive ion etching (RIE) chamber using a plasma process to get a desired ratio between the etch rate of the sacrificial profiling material and the underlying substrate material. The etching step itself can be broken down into multiple coarse and fine steps, where a substantial amount of material can be removed in the coarse steps with high etch rates for high throughput, with the fine steps correcting the errors in the desired profile. In one embodiment, intermediate metrology can be conducted between the coarse and fine steps. Furthermore, in some applications, an additional uniform film may be deposited on the nP3 process film. For example, a uniform metal layer may be deposited after the nP3 process such that it can render optical reflective properties with the appropriate profile to a substrate.

In one embodiment, an exemplar application of the nP3 process for precision optics is semiconductor optical lithography, metrology and inspection equipment.

An exemplar application for optical elements that are fabricated using the nP3 process, include multi-lens optical systems that are used during semiconductor optical lithography, imaging, inspection, metrology, microscopy, characterization, cameras, and other systems that require multi-lens columns. In one embodiment, the nP3 process may be combined with RIE. Current state-of-the-art semiconductor patterning includes feature sizes that are well below 100 nm, and in some cases approaching as low as 10 nm. For such high-resolution features, visible wavelengths are no longer sufficient as resolution is directly proportional to the wavelength. Thus, electromagnetic radiation deep in the UV spectrum is needed. Some common wavelengths that are used include 248 nm (Hg vapor), 193 nm (excimer laser) and 157 nm (vacuum UV). At the same time, resolution is increased with increasing numerical aperture of the system, typically greater than 0.9. This can theoretically be achieved by using large diameter lenses. However, these lenses have been traditionally difficult and expensive to fabricate, align and mount in a system. In order to reconcile these constraints, such optical systems are usually designed with a large number of lens elements, typically exceeding 10. By using multiple elements, a high numerical aperture can be achieved by using smaller elements that individually have a lower numerical aperture, but can function together to obtain the desired values for numerical aperture.

However, the use of multiple elements in the optical system introduces other difficulties. One of those difficulties is the presence of “gaps” between individual elements. Ideally, one would like to use optical cements in those gaps, that allow minimal refractive index mismatch across the optical element-gap interface. But the use of excimer lasers and other UV radiation can degrade the quality of those cements rapidly thereby precluding the use of such cements. Hence, instead of cements, the gaps can be let as is, i.e., the gaps can be air gaps. This causes a high refractive index mismatch between the optical element and the air gap, making it important for the optical system to be designed in such a way that the angles of incidence and refraction do not exceed the critical angle for total internal reflection. Moreover, the overall optical system also needs to be designed in such a way that the total optical aberrations in the system do not exceed values that can distort images beyond desired tolerances. Typical specifications for optical aberrations include better than λ/10 peak-to-valley (P-V) and/or better than λ/30 root mean square (RMS) optical path difference error for the overall system, and a Strehl ratio (quality of optical image formation of optical elements) of at least 0.9, and often more than 0.95, where λ is the wavelength of light used. These specifications typically also transfer directly to the individual elements themselves without much modification. Such tight performance specifications translate to strict fabrication tolerances, thus increasing the cost of individual elements. Moreover, the multi-lens optical system can also have individual elements that are dedicated to the control of specific aberrations, such as polarization aberrations, on-axis aberrations (e.g., spherical aberrations) and off-axis aberrations (e.g., coma). Also, at short wavelengths, chromatic aberrations can also become significant in spite of using substantially monochromatic light sources, and may need to be corrected using precise doublet and/or triplet lenses. For example, fused silica displays a refractive index change of ˜0.007 across a bandwidth of +/−5 nm at 248 nm wavelength. A similar refractive index change is observed across much of the entire visible spectrum for BK-7 glass.

The nature of these aberrations is also determined after the mounting and alignment of individual elements. Hence, the optical performance specifications also lead to tolerances in the mounting and alignment of individual elements, especially given that during transportation, such elements and their mounts can be subject to temperature ranges from −40° C. to 60° C. One or more elements in the column can be allowed to be adjusted or translated to minimize the overall aberrations in the system during the final qualification of the system. These aberrations may consist of polarization aberrations, chromatic aberrations and both on- and off-axis aberrations.

The numerical aperture (NA) and the optical aberrations may also influence the achievable magnification of the system, which coupled with the size of the sensor array, leads to the definition of a field of view. As a result, this may be an important consideration since it is desirable to have a large field of view to maximize system throughput. Typically, if NA is increased, the working distance is decreased, the resolution is increased, magnification is increased, and the field of view is decreased. If the aberration profiles can be precisely controlled over large areas, high NA (high magnification) can be achieved over larger fields of view. The principles of the present invention disclosed herein can increase the field of view without compromising the NA of the system. For example, the field of view of the multi-lens column is greater than 250 square millimeters, where the multi-lens column is used for projection lithography. For imaging systems, the field of view is also dependent on the size of the imaging sensor, and can be given as a function of the magnification with the sensor size. For example, for an imaging sensor of 100 mm diagonal width, and magnification is 1000×, the field of view would have a diagonal width of 0.1 mm. Large magnifications are important for higher resolution. However, such large magnifications are possible only when the NA of the system is high, typically exceeding 0.9, and ideally above 0.95, where the achievable NA is a function of the aberrations in the system. For imaging systems to achieve high throughput with low aberrations, it is desirable to have fields of view that can exceed 100 micrometers in diagonal width, and ideally above 1 mm in diagonal width. For illumination systems, such as projection optics for lithography, a high NA can be achieved without the constraint of a fixed size imaging sensor. Water immersion can be used to increase the NA to more than 1.9. For such systems, large fields of view can be enabled along with high numerical aperture at a magnification typically lower than 10× (usually 1× or demagnification of 4-5×). Typical lithography systems use projection scanning, and have fields of view of approximately 26 mm×5 mm. Fabricating large field of view, high NA optics requires a system of many lens elements (5-15, for example), and each of these lens elements has to be polished to high precision and assembled precisely. Therefore, the overall yield of the optical system depends on the product of the yield of each of these precise lenses. This can lead to very low yields which can make creating such lens systems prohibitively expensive (or impractical).

An embodiment of the present invention circumvents this problem by reducing the requirements on a plurality of the lenses in the lens system and emphasizing the fabrication of one or a few precise corrector plates with complicated profiles that can compensate for the reduced requirements for a plurality of the lenses. This can enable fabrication of high NA, high field of view, and high magnification lens systems by enhancing the yield of the overall system as only a minority of elements require high precision.

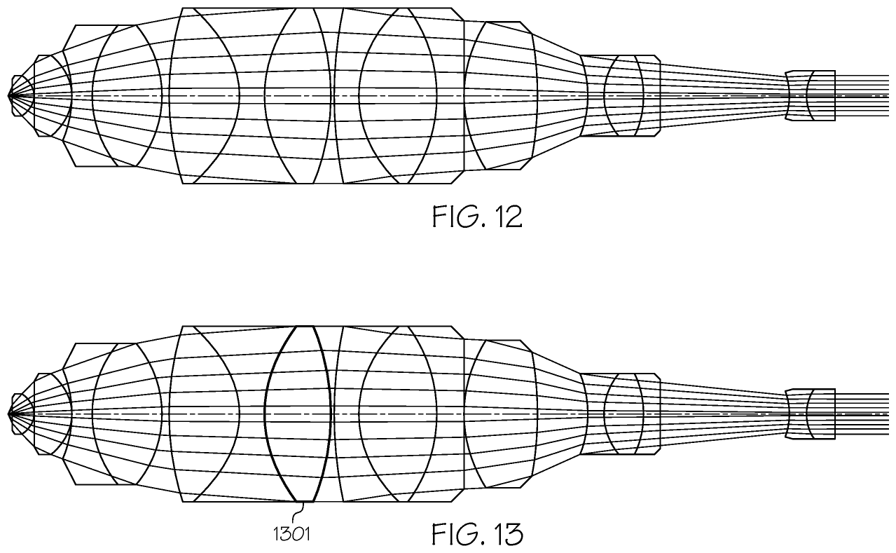

FIG. 12 illustrates an example of a multi-lens optical system in accordance with an embodiment of the present invention.

In one embodiment, use of the nP3 process may be combined with RIE for fabricating elements for use in multi-lens optical systems, as shown in FIG. 12, for semiconductor optical imaging, lithography, metrology, microscopy, inspection, characterization, diagnostics, cameras, and other systems needing multi-lens columns. This process offers precision control over the profile of one or more optical elements that can be used in such systems. These elements can either be lenses that are nominally curved (spherical, aspheric, freeform, toric, etc.) or plates that are nominally flat (e.g., windows). Furthermore, in one embodiment, the use of a multi-lens optical system with one or more elements fabricated using the nP3 process may be combined with RIE. Such one or more nP3 elements can be directly part of the original system design (shown in FIG. 13), and the use of the nP3 process offers greater precision and consequently, better optical performance than the current state-of-the-art, presumably, at lower or similar cost structures. FIG. 13 illustrates an element 1301 fabricated using nP3 that is part of the original system in accordance with an embodiment of the present invention.

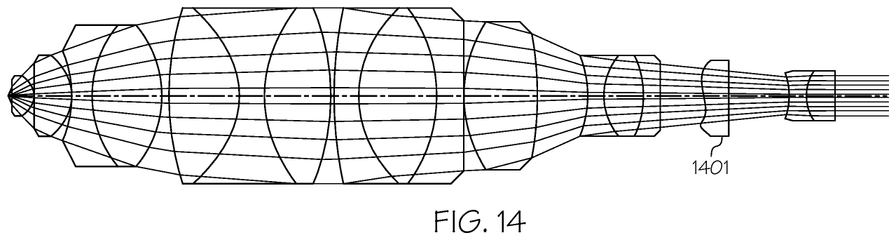

The design and fabrication of the nP3 elements can be done after measuring the aberrations and optical performance of the system without the nP3 element(s). Such one or more nP3 elements can also be custom corrector plates (shown in FIG. 14), that are added to the original system to compensate for aberrations that arise in the fabrication and assembly of the system. FIG. 14 illustrates corrector plates 1401 that are fabricated using the nP3 process and added to the original system to improve optical performance and relieve design, fabrication and assembly tolerances for other elements in the system in accordance with an embodiment.

These aberrations can include on-axis, off-axis, chromatic, monochromatic, polarization and other aberrations. In one embodiment, these aberrations are measured after the assembly of the system and prior to the assembly of the nP3 corrector plate(s). This can allow the non-nP3 elements in the optical system to be fabricated and assembled with more relaxed tolerances, while the one or more nP3 elements have the necessary precision of fabrication and assembly to compensate for the errors arising from the other elements, where such errors are measured prior to the final assembly of the system. Hence, such nP3 elements are designed, fabricated and assembled after the other elements in the lens column are assembled.

In one embodiment, such optical nP3 elements are used for darkfield imaging, lightfield imaging, confocal microscopy, and high numerical aperture objectives.

In one embodiment, such optical nP3 elements are used with air gaps during assembly.

Also, enabled by the nP3 process, such one or more nP3 elements can also lead to novel optical system design, perhaps with fewer elements, or with larger area elements, that can achieve the desired optical performance without the need for as many elements as in an optical system designed using optical elements fabricated using conventional polishing or grinding processes. Such one or more nP3 elements can also enable larger fields of view and enhance system throughput. Such one or more nP3 elements may also be fabricated from materials, such as SiO₂ (including UV-grade fused silica, fused quartz, and other varieties of glasses), Al₂O₃, MgF₂, CaF2, ZnS, etc. Some materials (referred to herein as “unetchable materials”), such as MgF₂ and CaF₂, may be difficult to etch or substantially unetchable in a plasma chamber because they may not readily form volatile byproducts by reacting with commonly used etch gases (e.g., oxygen, argon, CHF₃, HBr, Cl₂, etc.). For such materials, an intermediate sacrificial film of SiₓO_{y}, SiₓN_{y}, SiₓO_{y}N_{z}, or other oxides and nitrides that can be etched using RIE, can be deposited on the substrate using a chemical vapor deposition (CVD) or physical vapor deposition (PVD) process. This intermediate sacrificial film can then be profiled using nP3 in combination with RIE, such that the underlying unetchable material is substantially covered with the sacrificial material. Such sacrificial material can have a refractive index that is substantially matched with the underlying unetchable material such that it forms a seamless interface with the optical element. Such sacrificial material can have a thickness that is low enough such that any loss in optical performance because of the presence of the sacrificial material is minimized. Such sacrificial material may be deposited on a textured layer of the unetchable material such that the interface behaves like a moth-eye structure and minimizes any losses due to reflection. Such sacrificial material may also be polished or ground (using techniques, such as sub-aperture polishing for example) such that the material removal rates for both the sacrificial material and the unetchable material are substantially similar, leading to a substantial transfer of the profile into the unetchable material. Most polishing processes follow the Preston equation, that states that the material removal rate is directly proportional to the polishing pressure and the relative velocity of the substrate. The coefficient of proportionality is called the Preston coefficient and is typically obtained experimentally. The polishing process can be designed or optimized to ensure that the value of the Preston coefficient is similar for both the sacrificial material and the unetchable material. Any systematic errors in the polishing or grinding process can be compensated for in the nP3 profiling of the sacrificial material.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for fabricating one or more elements in a multi-lens column, the method comprising:
dispensing drops of ultraviolet (UV)-curable liquid by an inkjet on a substrate;
forming a non-uniform liquid film by spreading and merging of said inkjetted drops;
locally heating said film;
curing said film by exposing said film to UV light, wherein said cured film together with said substrate form an element of said multi-lens column; and
performing optical metrology on said cured film and said substrate.

2. The method as recited in claim 1, wherein said spreading and merging of said inkjetted drops is enabled by a superstrate.

3. The method as recited in claim 1, wherein said optical metrology is performed simultaneously with said formation of said non-uniform liquid film.

4. The method as recited in claim 1, wherein said element of said multi-lens column formed from said cured film and said substrate correct optical aberrations of one or more other elements of said multi-lens column.

5. The method as recited in claim 1, wherein said local heating of said film is performed using one or more of the following: an infrared light source projected using a digital micromirror device array, distributed microheaters, and an infrared laser source mounted on a stage.

6. A method for fabricating one or more elements in a multi-lens column, the method comprising:
depositing a cured film on a surface of an imprecise lens to correct external aberrations or inherent aberrations using a nanoscale precise programmable profiling process, wherein said nanoscale precision programming profiling process comprises:
dispensing drops of ultraviolet (UV)-curable liquid by an inkjet on a substrate;
forming a non-uniform liquid film by spreading and merging of said inkjetted drops;
locally heating said film; and
curing said film by exposing it to UV light;
transferring a profile of said cured film into said substrate by dry etch, wherein said substrate with said transferred profile of said cured film forms an element of said multi-lens column; and
performing optical metrology on said substrate.

7. The method as recited in claim 6, wherein said spreading and merging of said inkjetted drops is enabled by a superstrate.

8-9. (canceled)

10. The method as recited in claim 6, wherein said local heating of said film is performed using one or more of the following: an infrared light source projected using a digital micromirror device array, distributed microheaters, and an infrared laser source mounted on a stage.

11. A multi-lens column, comprising:
one or more optical elements fabricated using a nanoscale precision programmable profiling process and a dry etch process, wherein said nanoscale precision programming profiling process comprises:
dispensing drops of ultraviolet (UV)-curable liquid by an inkjet on a substrate;
forming a non-uniform liquid film by spreading and merging of said inkjetted drops;
locally heating said film; and
curing said film by exposing it to UV light; and
transferring a profile of said cured film into said substrate by said dry etch process, wherein said substrate with said transferred profile of said cured film forms an optical element of said multi-lens column.

12. The multi-lens column as recited in claim 11, wherein said one or more optical elements comprise corrector plates that correct one or more of the following: on-axis aberrations, off-axis aberrations, chromatic aberrations, and polarization aberrations.

13. The multi-lens column as recited in claim 11, wherein said one or more optical elements are used in one or more of the following: semiconductor lithography, imaging, microscopy, inspection, characterization, metrology, and cameras.

14. (canceled)

15. The multi-lens column as recited in claim 11, wherein overall aberrations in said multi-lens column are better than λ/10 peak-to-valley (P-V) optical path difference error, wherein said λ corresponds to a wavelength of light.

16. The multi-lens column as recited in claim 11, wherein overall aberrations in said multi-lens column are better than λ/30 root mean square (RMS) optical path difference error, wherein said λ corresponds to a wavelength of light.

17. The multi-lens column as recited in claim 11, wherein a quality of optical image formation of said one or more optical elements has a Strehl ratio greater than 0.95.

18. The multi-lens column as recited in claim 11, wherein a numeral aperture of said one or more optical elements is greater than 0.90.

19. The multi-lens column as recited in claim 11, wherein said one or more optical elements is made of one of the following materials: SiO₂, UV-grade fused silica, CaF₂, MgF₂, Al₂O₃, and ZnS.

20. The multi-lens column as recited in claim 11, wherein said one or more optical elements are designed, fabricated and assembled after other elements in said multi-lens column are assembled, wherein said one or more optical elements compensate for aberrations of said other assembled elements.

21. (canceled)

22. The multi-lens column as recited in claim 11, wherein a field of view of said multi-lens column is greater than 100 micrometers in diagonal width, wherein said multi-lens column is used for imaging.

23. The multi-lens column as recited in claim 11, wherein a field of view of said multi-lens column is greater than 1 millimeter in diagonal width, wherein said multi-lens column is used for imaging.

24. The multi-lens column as recited in claim 11, wherein a field of view of said multi-lens column is greater than 250 square millimeters, wherein said multi-lens column is used for projection lithography.

25. The multi-lens column as recited in claim 11, wherein said one or more optical elements is made of a material that is unetchable in a reactive ion etching chamber, wherein a sacrificial material is deposited on said unetchable material.

26. The multi-lens column as recited in claim 25, wherein said unetchable material has a textured interface with said sacrificial material.

27. The multi-lens column as recited in claim 25, wherein said sacrificial material and said unetchable material are polished at substantially similar rates.

28. (canceled)

29. The multi-lens column as recited in claim 25, wherein said sacrificial material has a refractive index substantially similar to said unetchable material.
